(19) United States
(12) Patent Application Publication
(10) Pub. No.: US 2021/0238971 A1
(43) Pub. Date: Aug. 5, 2021

(54) PRODUCTION MANAGEMENT OF WELLS BASED ON DETERMINED ALLOCATED WELL PRODUCTION RATES

(71) Applicant: SAUDI ARABIAN OIL COMPANY, DHAHRAN (SA)

(72) Inventor: PAUL CRUMPTON, Dhahran (SA)

(21) Appl. No.: 16/780,139

(22) Filed: Feb. 3, 2020

(51) Int. Cl. E21B 43/14; E21B 41/00

(52) U.S. Cl. CPC E21B 43/14; G06F 30/20; E21B 41/0092

(57) ABSTRACT

Fluid production among individual wells of a producing hydrocarbon reservoir is allocated based on determined production rates. Wells with more desirable production characteristics (such as: lower water cut—or ratio of water produced compared to the volume of total liquids produced; or lower gas/oil ratio in the produced fluids from the reservoir) are allocated with higher production rates to meet a target fluid production rate from the reservoir. Reservoir engineers thus are provided a capability to control reservoir production to meet a target production rate of hydrocarbons without excess production of water and gas among the produced liquids.

### BACKGROUND OF THE INVENTION

### 1. Field of the Invention

The present invention relates to management of fluid production among wells of a producing hydrocarbon reservoir based on determined allocated well production rates.

### 2. Description of the Related Art

Reservoir simulators are used extensively for forecasts in field development plans for production of oil from subsurface hydrocarbon reservoirs in oil and gas fields. It is a common practice for a reservoir with a number of the wells to have an established target or “plateau” production rate of oil for a group of wells. Reservoir engineers then evaluate projected production from the wells to meet the target production rate. A reservoir with such a group of wells typically has a sophisticated well management system that allocate well rates to a group of wells in the reservoir to reach the target or “plateau” rate. A computerized reservoir simulator then predicts production scenarios based on the allocated production rates of the wells in the group and an important production control and management system for exploitation of oil and gas reserves.

When a reservoir engineers wants to establish a target rate for a field which has water or gas (or both) handling constraints, it would be desirable to preferentially establish production to wells with low water cut (WWCT) or gas/oil ratio (GOR). This is done to produce the required production rate of oil according to the established target production rate for the field, without producing excess amounts of water or gas in the production fluid from the well.

So far as is known, typical production allocation among wells in a group has been to allocate production rates proportional to the maximum achievable rate that each individual well can produce for a given phase. For an oil production well, that is the maximum oil rate that particular well can produce. So for an oil target production rate, the well which can produce the maximum oil will be given the largest share of the target, regardless of how much water or gas is also produced by that well. This allocation was based on allocating a larger share of the production allocation to a well which can produce the most oil.

However, there are disadvantages to this allocation methodology. The most productive wells can be allocated a rate which is too high. This can cause unnecessary coning issues, with gas or water infiltrating near-wellbore areas, and reducing oil production from the well. In such cases, overproduction from wells can reduce the overall target production rate.

Further, conventional oil production allocation methods did not take into account the volume of water or gas which was being produced along with the oil, and so the group of wells cumulatively could produce unwanted excess water or gas. Therefore, conventional allocation did not take into account circumstances or conditions of individual wells in the group.

In some instances, production allocation has been made by a methodology known as weight rated allocation. This type well production allocation has been a complex one, based on mass balance relationships, well pressures and formation parameters such as permeability, viscosity and the like. This allocation methodology requires selection of values for coefficients for a large number of these parameters and relationships which affect production from wells in a reservoir.

There were thus several problems with the weight rated allocation methodology. There were a number of coefficients required to be chosen for each well in order to perform weight rated allocation. It was often difficult for a reservoir engineer to understand and choose which coefficients were to be selected and applied for the weight rated allocation methodology. In addition, it was difficult to adjust and tune parameter values in order to satisfactorily obtain the target production rate. The weight allocated production method also could not be adapted to account for other well conditions, such as the presence of hydrogen sulfide (H₂S) in the production of fluids from the reservoir. In addition, unless particular care was taken in selection of parameter values, the weight rated allocation method determinations could become unstable and produce unexpectedly large changes in allocated production rates, or production rates which were physically impossible of achievement. There were additionally difficulties in resolving conflicts among the production rate allocations for the various wells in a group.

### SUMMARY OF THE INVENTION

Briefly, the present invention provides a new and improved method of controlling production of a hydrocarbon fluid at an assigned production target rate from a plurality of production wells of a subsurface hydrocarbon reservoir with a well production and control system, based on allocated production rates among the plurality of production wells determined by a data processing system. The data processing system includes a processor, a memory and a reservoir simulator.

Real time production pressure and flow rates during production of fluids from the production wells are received in the data processing system memory. Real time downhole pressure measures during the production of fluids in the production wells are also received in the data processing system memory. A target production rate for the hydrocarbon fluid from the group of wells is also received in the data processing system memory.

The data processing system processor determines production allocations for individual wells of the group of wells. The reservoir simulator performs a simulation of production of fluids from the individual wells of the reservoir to determine whether the allocated production from the wells matches the well group reduction target rate. Production rates of the production wells are then adjusted with the well production and control system based on the determined production allocation rates among the wells of the reservoir.

The present invention also provides a new and improved system for controlling production of a hydrocarbon fluid at an assigned production target rate from a plurality of production wells of a subsurface hydrocarbon reservoir with a well production and control system, based on allocated production rates among the plurality of production wells. The system includes a well production and control system to control production of fluids from individual production wells of the plurality of production wells, and a plurality of permanent downhole pressure measurement sensors in less than all of the production wells to measure downhole pressure for such production wells to serve as observation wells.

The system according to the present invention further includes a data processing system determining allocated production rates among the plurality of wells. The data processing system includes a memory receiving real time production pressure and flow rates during production of fluids from the production wells, as well as real time downhole pressure measures during the production of fluids in the production wells, and also a target production rate for production of the hydrocarbon fluid from the group of wells.

The data processing system also includes a processor determining production allocations for individual wells of the group of wells, and a reservoir simulator performing a simulation of production of fluids from the individual wells of the reservoir to determine whether the allocated production from the wells matches the well group reduction target rate. The well production and control system adjusts production rates of the production wells based on the determined production allocation rates among the wells of the reservoir.

The present invention also provides a new and improved data storage device which has stored in a non-transitory computer readable medium computer operable instructions for causing a data processing system to control production of a hydrocarbon fluid at an assigned production target rate from a plurality of production wells of a subsurface hydrocarbon reservoir with a well production and control system. The control of production is based on allocated production rates among the plurality of production wells determined by a data processing system, which has a processor, a memory and a reservoir simulator,

The instructions stored in the data storage device cause the data processing system to receive in the data processing system memory real time production pressure and flow rates during production of fluids from the production wells, and also real time downhole pressure measures during the production of fluids in the production wells. The instructions further cause the data processing system to receive in memory a target production rate for hydrocarbons from the group of wells.

The instructions stored in the data storage device cause the processor of the data processing system to determine production allocations for individual wells of the group of wells. The stored instructions cause the reservoir simulator to perform a simulation of production of fluids from the individual wells of the reservoir to determine whether the allocated production from the wells matches the well group reduction target rate for adjusting production rates of the production wells with the well production and control system based on the determined production allocation rates among the wells of the reservoir.

### BRIEF DESCRIPTION OF THE DRAWINGS

FIG. 1 is a schematic diagram of a hydrocarbon reservoir and production control system including a production downhole pressure management system.

FIG. 2 is a functional block diagram of a set of processing steps for production management of wells based on determined allocated well production rates according to the present invention.

FIG. 3 is a functional block diagram of a set of data processing steps performed to determine allocated well production rates in a data processing system during production management of wells based on determined allocated well production rates according to the present invention.

FIG. 4 is a schematic block diagram of a data processing system for determination of allocated well production rates during production management of wells in a subsurface hydrocarbon reservoir according to the present invention.

FIGS. 5, 6 and 7 are diagrams illustrating schematically determination of allocated well production rates during the processing according to FIG. 3.

FIG. 8 is a schematic diagram of a set of data processing steps performed in a data processing system for allocation of production strategies among wells of the reservoir of FIG. 1 according to the present invention.

FIG. 9 is a plot of an example allocation of production strategies among wells of the reservoir of FIG. 1 according to the present invention.

FIGS. 10A and 10B are example comparative plots of results from reservoir simulation for well production obtained according to the present invention in contrast with conventional methods of production allocation.

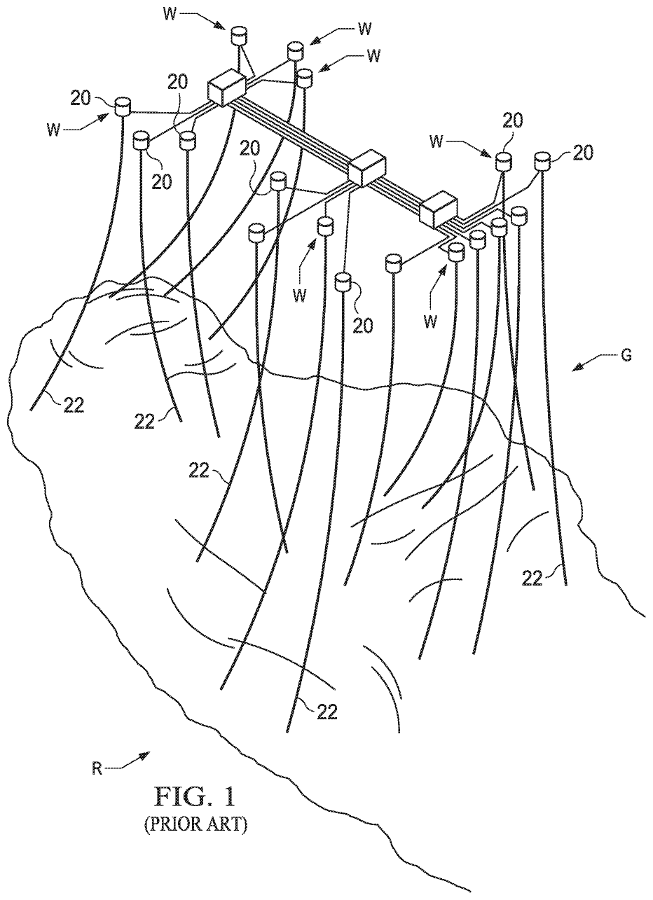

FIGS. 1A and 11B are example comparative plots of results from reservoir simulation for well production obtained according to the present invention in contrast with conventional methods of production allocation.

### DETAILED DESCRIPTION OF THE PREFERRED EMBODIMENTS

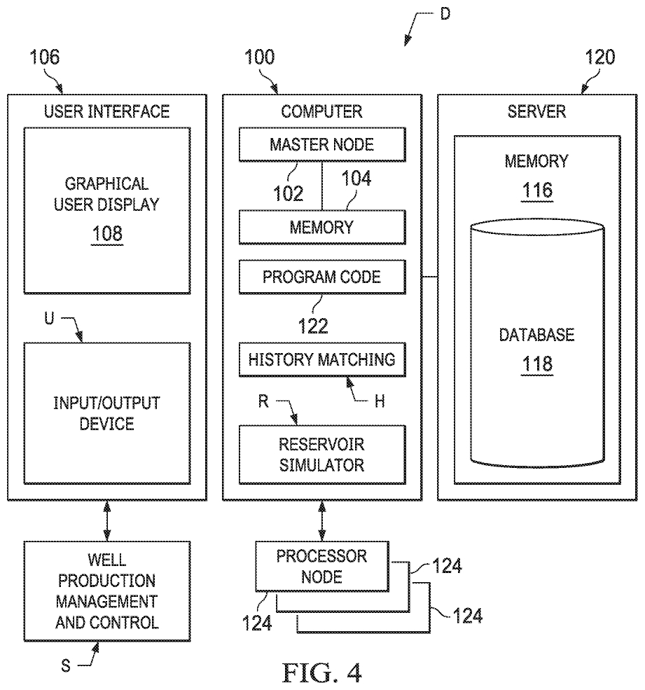

In the drawings, FIG. 1 illustrates an example placement of a group G of wells W from a portion of a large hydrocarbon producing reservoir R. The wells in the group G typically include production wells, injection wells and observation wells and are spaced over the extent of the reservoir. The wells W are provided with a suitable conventional reservoir production management and control system with wellhead surface controls; well production data sensors including flowmeters, pressure and temperature sensors for well production data acquisition; and well flow rate and pressure control valves and mechanisms. Such a system is indicated schematically at S in FIG. 4 providing intercommunication with a data processing system D, as will be described.

As indicated, certain ones of the wells W represented by the group G are provided with permanent downhole measurement systems 20, which are known as PDHMS. The PDHMS 20 may, for example be of the type described in U.S. Pat. Nos. 8,078,328 and 8,312,320, commonly owned by the assignee of the present application. The subject matter disclosed in U.S. Pat. Nos. 8,078,328 and 8,312,320 is incorporated herein by reference.

The PDHMS 20 include surface units which receive reservoir and well data in real time from downhole sensors 22. The downhole sensors 22 obtain data of interest, and for the purposes of the present invention the downhole sensors include downhole pressure and temperature sensors located in the wells W at selected depths and positions in the selected group G of wells among the much larger number of wells in the reservoir.

The downhole sensors 22 furnish the collected real-time pressure and temperature data from the wells W in which they are installed, and a supervisory control and data acquisition (SCADA) system with a host computer or data processing system D (FIG. 4) collects and organizes the collected data from the wells in the group G. The PDHMS 20 also includes sensors to record production and injection data for the injection wells in the group G, which data is also collected and organized by the supervisory control and data acquisition.

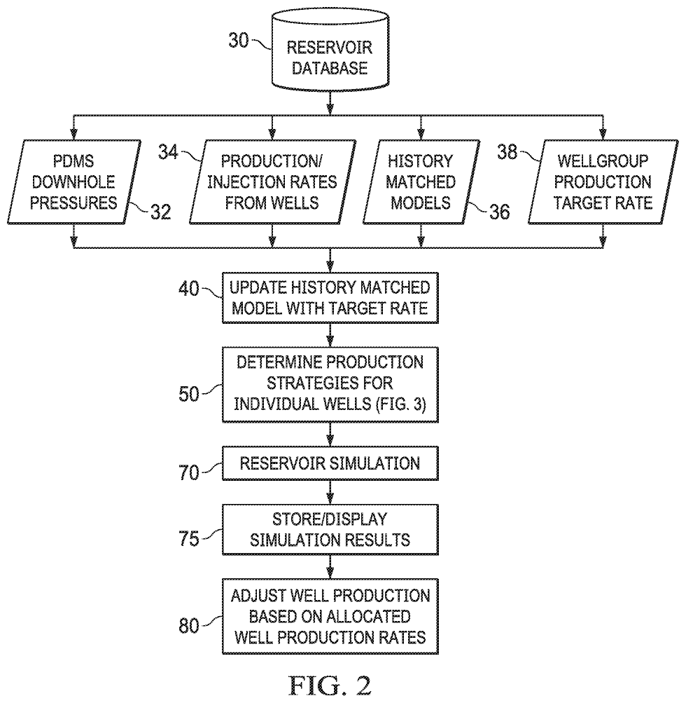

Turning to FIG. 2, a flow chart F displays a set of processor steps performed according to the methodology of the present invention in conjunction with a data processing system D (FIG. 4) for production management of wells based on determined allocated well production rates according to the present invention. The flowchart F indicates the operating methodology of production management of wells based on determined allocated well production rates including a computer processing sequence and computations takings place in the data processing system D for production management.

As indicated at step 30, the methodology of the present invention is based on input reservoir data stored in the data processing system D. The input reservoir data includes downhole pressures measured as described above at production, injection and observation wells W by the PDHMS as shown in FIG. 1, as well as the real time production and injection rates obtained by the PDHMS 20 during production from production wells and injection from injection wells W.

During step 30, the real time production and injection rates, and the downhole pressures are filtered to remove short term transients, and stored for use as daily data input entries as downhole pressures in step 32 and production and injection rates in step 34. The real time well pressure values measured at downhole gauges are preferably converted to flowing bottom hole pressure (FBHP) values at the top perforations based on the calculated pressure gradient between the two gauges installed in the well, and these FBHP values transformed into reservoir pressures though a well model.

As indicated at an input to step 36, the production and injection rates in step 34 stored during step 30 are used to update a history match model which is run in step 40 with a history match module H of the data processing system D (FIG. 4) to generate reservoir production rates at selected times of interest known as time slices.

During step 36, the history matching module H of the data processing system D adjusts the model of the reservoir R so that the model closely reproduces past or actual historical production performance and other behavior of the reservoir during production to date.

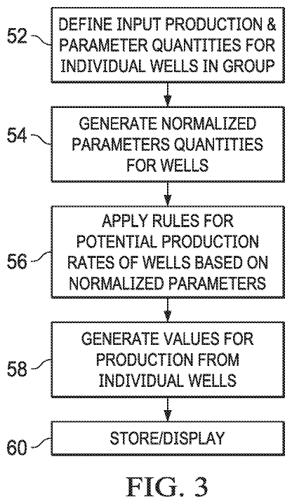

The data processing system D is also provided as indicated during step 38 with a well group target production rate. The well group target production rate is received as an input by a user input device U (FIG. 4). The production and injection rates are entered as input data and provided to the history match module H. during step 40, the history match model resulting from step 36 is then updated based on the production and injection rates provided during step 38. Processing then proceeds to step 50 (FIGS. 2 and 3) to determine the production strategies for individual wells W of the group G according to the present invention.

Turning to FIG. 3, determination of the production strategies for individual wells W during step begins with step 52, during which defined input production and parameter quantities are received for individual wells in the group resulting from steps 32, 34, 36, 38 and 40. Step 54 follows during which the defined input production and parameter quantities received during step 52 are normalized to each have a data range from 0 through 1 instead of their actual measured numerical values.

Step 56 is next performed and rules are applied for potential production rates of the individual wells W based on the generated normalized parameter quantities obtained during step 54. Then during step 58 values are generated for production rates for the individual wells W in the group based on the rules applied during step 56. The performance of steps 56 and 58 utilizes a methodology known as fuzzy logic and will be described in more detail in subsequent portions of this description. Step 60 follows and the generated production rate values for the individual wells W resulted are stored in memory of the data processing system D. The stored production rate values for the individual wells may if desired be displayed for evaluation and analysis by reservoir engineers.

After performance of step 60, processing proceeds to step 70 (FIG. 2). During step 70 the generated production rate values for the individual wells from step 60 together with the updated history match model H resulting from step 40 are provided as inputs for a reservoir simulation during step 70 using a suitable reservoir simulator S of the data processing system D. Such a reservoir simulator may, for example, be the reservoir simulator known as GigaPOWERS, and described in SPE 142297, “New Frontiers in Large Scale Reservoir Simulation”, 2011, (Dogru) and SPE 119272, “A Next-Generation Parallel Reservoir Simulator for Giant Reservoirs”, 2009, (Dogru).

Step 75 follows during which and the reservoir simulation results are stored in memory of the data processing system D, and are displayed for evaluation and analysis by reservoir engineers. The reservoir engineers then during step 80 with the reservoir production management and control system is able to make appropriate adjustments of well production from the wells W.

### Well Management

For any well management system of a reservoir, a potential production quantity Pᵢ calculated for all wells. The potential production calculation is performed to determine to define a production allocation strategy. As has been discussed, there are at least two prior types of production strategies which had shortcomings and presented technological problems.

As an example for a group of wells has a target T a production allocation strategy an aggregate production quantity for the group of wells based on individual production allocations Q for each of the i wells in the group can be expressed analytically as:

$$T = {\sum }_{i} {Q}_{i}$$

Such that

$$\frac{{Q}_{j}}{{P}_{j}} = c \text{∀} j$$

Where T is the target rate for the group, Qᵢ is the production rate for every well i in the group. The formula above is simplified for the purpose of explanation and omits factors caused by consideration of complexity of additional constraints that apply to the wells.

For example, if a well x and a well y have potentials Pₓ and P_{y}, and if the potential of well x is twice that of well y, or:

Pₓ=2P_{y}

then the well x will produce twice the amount of fluids as well y.

Traditionally the quantity Pᵢ for a well i is set to the maximum achievable rate. The well can then produce for a given hydrocarbon phase, such as oil, the maximum oil rate that the well can produce. For an aggregate oil target rate among a group of wells, the well which can produce the maximum oil is given the largest share of the target, regardless of how much water or gas it produces. This approach is to let the well which can produce the most, take the largest pro rata share of the allocation.

However, this is caused technological problems as there were disadvantages to using this approach even though it was simpler than weight rated allocation. The most productive wells could be allocated a rate which was too high and possibly caused unnecessary water and gas coning issues, this overproduction can reduce overall production rate. Further, the volume of water which was produced along with the oil was not taken into account in production planning, and the group of wells may produce too much water. Similarly, no account of the gas which was produced along with the oil is accounted for during production planning, and so the well group may produce too much gas.

### Production Allocation by Fuzzy Logic

Fuzzy Logic in the context of the present invention is a methodology which is utilized for allocating production rates for wells. Thus, the complicated assignment of parameter values for weight rated allocation is not required. Further, reservoir engineers are allowed to determine production allocation rates among wells and take into account particular circumstances in the wells, such as excess water or gas in the well fluids of producing wells which previously had been assigned a higher production allocations due to their high production rates. With the present invention, production rates define Pᵢ are assigned during processing step 52 (FIG. 3) among the wells W according to Fuzzy Logic methodology. Production rate allocation determination in this manner as four components, as will be described.

### 1. Define Input

As example, a suitable number of reservoir well characteristic parameters or quantities for each well i of the N_{w} wells are defined, for example:
WWCT Water cut (the ratio of water to liquid production)
GOR (Gas to oil ratio)
POT Maximum production rate a well can achieve.
   It should be understood that the foregoing list as an example and that other inputs could also be included for other quantities such as hydrogen sulfide (H₂S) production, salinity concentration, polymer concentration, surfactant concentration, reservoir engineering workflows and the like. Other possible well parameters or quantities according to the present invention include, for example: C02 concentration, GLR (gas liquid ratio), WGR (water gas ratio), static pressure of the well, and thermal energy.

### 2. Fuzzification

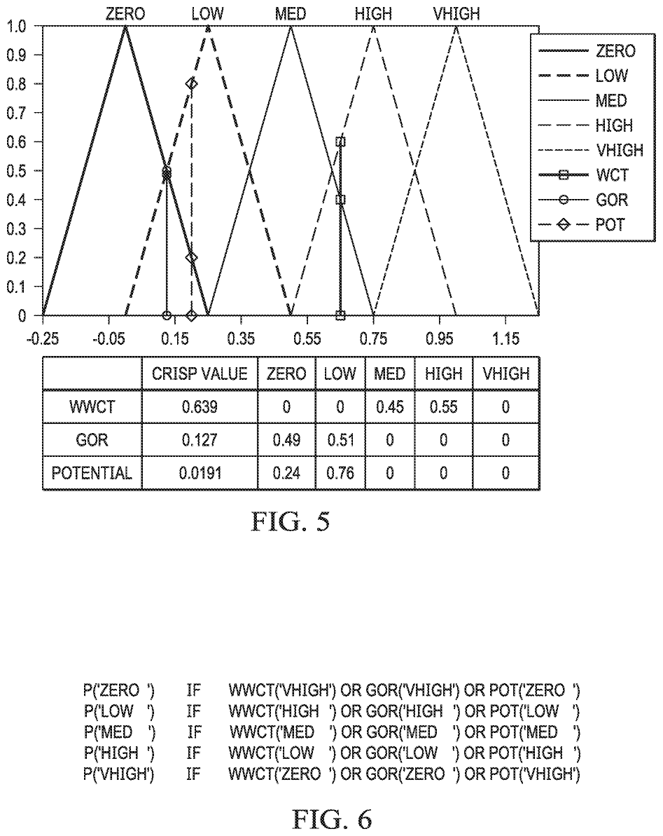

In this functionality, what are known as hat-function basis functions are used as each crisp input quality is split into a FUZZY set, as illustrated in FIG. 5.

As shown in FIG. 5, the input quantities of water cut WWCT, gas/oil ratio GOR and production rate or POTENTIAL are normalized during step 54 to values between zero and one, as opposed to measures values. Further as shown in FIG. 5 each fuzzy set is composed of a suitable number of what are known as members. In this example the members are: “ZERO”, “LOW”, MED”, “HIGH” and “VERY-HIGH.” The reservoir engineer defines a range of values for the five members of the fuzzy set, such as a value for a VERY-HIGH water cut (WWCT) or VERY-HIGH gas/oil ratio (GOR). Each member of a Fuzzy set is associated with a basis function, which are chosen to be what are known as “hat” functions. “Hat” functions for fuzzy logic methodology are used to establish “membership” in the fuzzy set from a crisp single value input. An important aspect of“hat” functions is that their non-zero values overlap. Consequently, for example, consider well water cut WWCT with a crisp value (0.639) as shown in FIG. 5 evaluated for membership in the fuzzy sets. The well water has a membership 0 of the ZERO hat function, membership 0 of LOW hat function, membership 0.45 from a MED hat function and 0.55 value from the HIGH membership function and 0 from the VHIGH hat function. Thus the original value of water cut (0.639) if broken into a fuzzy set is represented for membership as {0 (ZERO), 0 LOW, 0.45 (MED), 0.55 (HIGH), 0, VHIGH}.

As shown in FIG. 6, during the next stage of well production allocation according to the present invention in step 56 (FIG. 3) what are known as Linguistic Rules are applied. These rules are defined by the physical interrelation of the input quantities based on knowledge of the reservoir engineer about the field or reservoir. For example, it is known that where the water cut of a well is a high value, the potential production from the well is low.

As shown in the example of Linguistic Rules in FIG. 6, the POTENTIAL is ZERO, if: the WWCT is “VERY-HIGH”; or, the GOR is “VERY-HIGH:” or, if the POTENTIAL is “ZERO”. Another example Linguistic Rule in FIG. 6 is that the POTENTIAL is LOW, if: the WWCT is “HIGH”; or, the GOR is “HIGH;” or, if the POTENTIAL is “LOW.” Similarly, the POTENTIAL is MEDIUM, if: the WWCT is “MEDIUM”; or, the GOR is “MEDIUM” or, if the POTENTIAL is “MEDIUM.” Also, the POTENTIAL is HIGH, if: the WWCT is “LOW”; or, the GOR is “LOW” or, if the POTENTIAL is “HIGH.” A further example Linguistic Rule is that the POTENTIAL is VERY-HIGH, if: the WWCT is “ZERO”; or, the GOR is “ZERO” or, if the POTENTIAL is “VERY-HIGH.”

The fuzzy rules are evaluated using min/max inference, where AND is equivalent to min and OR is equivalent to MIN. With reference to the examples shown in FIG. 6, the membership of fuzzy set P(‘ZERO’) is set to the maximum of the fuzzy membership of WWCT(‘VHIGH’), GOR(‘VHIGH’) or POT(‘ZERO’). The fuzzy potential thus has in this example, ‘ZERO’ membership if the WWCT or GOR has ‘VHIGH’ membership or the POT has ‘ZERO’ membership. In contrast the fuzzy potential has non-zero ‘VHIGH’ membership (ie. P(‘VHIGH’) if the WWCT(‘ZERO’) or GOR(‘ZERO’) or POT(‘VHIGH’) has nonzero membership. These linguistic fuzzy rules translate engineering knowhow into a fuzzy output set. In contrast to traditional logic, all branches of the rules are evaluated.

### 3. De-Fuzzification

This component of the fuzzy logic methodology is performed during step 58 (FIG. 3), Step 58 performs this step by applying what is known as a center of gravity method. In this method the area under the membership height of each basis hat function is amalgamated, and the center of gravity of the resulting shaped area is evaluated. This processing converts the fuzzy set P into a crisp or precise value that can subsequently be used in reservoir simulation by the reservoir simulator. It is in this process that conflicts between the rules are resolved.

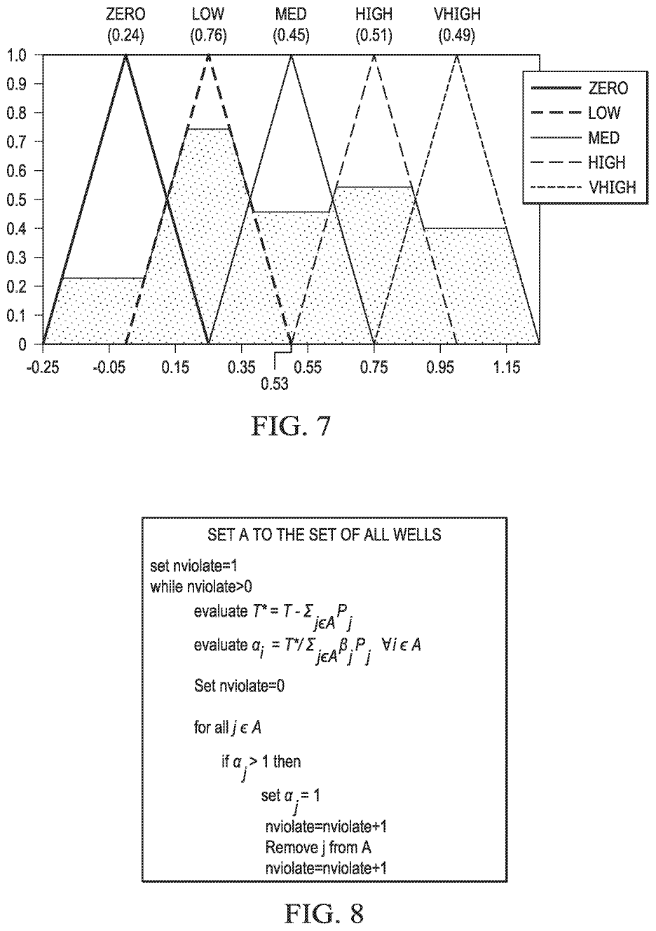

For instance, in the example of FIG. 7, the Fuzzy Potential has some membership “Very High” (0.49) and some membership “ZERO” (0.24). This arises because in this example the water cut WWCT is high, suggesting a lower potential; while the gas/oil ratio GOR is low, suggesting a higher potential. The de-fuzzification using the center of gravity method thus resolves conflicts by averaging the fuzzy membership. The ability to resolve these conflicts in a stable way when combined with calculating the potential of a well is an important feature of the processing to central hydrocarbon production from a group of wells at an assigned production target rate according to the present invention.

### Well Allocation Example

As an example of well production allocation according to the present invention, consider that the group G of wells is N_{w} in number. Each well in the group G has a maximum oil rate (or oil potential) of Pᵢ barrels/day for wells i=1, N_{w}. Furthermore this group of wells is assigned a target production rate or plateau of T oil barrels/day. The well production allocation can easily be generalized to targets of different phases (such as gas production target, or water target for injection wells).

Well production allocation according to the present invention determines a scaling factor (αᵢ) according to Equation (1) for each well i such that the aggregate of production rates for each well I=1, N_{w} when adjusted by the scaling factor αᵢ matches the target rate T, or:

T=Σᵢ₌₁^{N}^{_{w}}αᵢPᵢ (1)

There is however a condition regarding Equation (1) and that the target rate T must be susceptible of providing a physical solution regarding allocation. Specifically, the target rate T which is set must be less than the aggregate of total maximum oil production rate from the N_{w} wells in the group, as stated in Equation (2):

T<Σᵢ₌₁^{N}^{_{w}}Pᵢ (2)

If this condition is not present, the reservoir production management and control system sets each of the wells at a maximum production rate. In such a condition, the scaling factor for each well is set at unity (αᵢ=1 ∀i). However, the target production rate T cannot be physically obtained.

If, however, the reservoir is producing at the target or plateau rate, Equation (2) is applicable, the reservoir production management and control system must be adjusted by a determination of allocated production rates for each well (αᵢPᵢ).

In the case of earlier efforts of others, the most straightforward way chosen was to adjust production uniformly among the wells. Production at a uniform allocation was thus according to a relationship expressed in Equation (3):

$${α}_{i} = \frac{T}{{\sum }_{j = 1}^{{N}_{w}} {P}_{j}} \qquad ( 3 )$$

Thus, each well was scaled back from its maximum by the same fraction. This presented a problem because each well was being required to produce without regard to its current production circumstances. Examples of the problem were bad when the water cut (defined as production fraction of oil/liquid, WWCT) of the produced fluid was a high value, or if the gas oil ratio (defined as production fraction of gas/oil, WGOR) is high.

The present invention provides a capability for reservoir engineers to adjust the allocated production rates for individual wells and draw more heavily on production from wells with lower water or gas oil ratio in order to achieve the target production rate.

The present invention is based on a proportionality factor βᵢ for each well, by which a production allocation is determined which is to be proportional according to the proportionality factor βᵢ. This can be achieved as expressed in Equation (4):

$${α}_{i} = ( \frac{T}{{\sum }_{j = 1}^{{N}_{w}} {P}_{j}} ) {β}_{i} \qquad ( 4 )$$

The problem with Equation (4) is, as has been noted, that at maximum production it cannot be guaranteed that the aggregate production from the group of wells can meet the target production rate T, or αᵢ≤1. Thus some wells may be asked to produce more than the maximum Pᵢ which is a result which is not physically achievable. In order to enforce that the results of determination of allocated production rates are physically achievable, or αᵢ≤1, an iterative procedure to honor the proportional factor βᵢ according to the present invention is provided. The iterative procedure is shown in FIG. 8 in pseudo-code.

The iterative procedure in FIG. 8 when applied results in a set of wells, those not in set A, which are in maximum production, or on full blast, expressed analytically as (αᵢ=1 ∀i ∉A ). There is also a set of wells in which the production rates are scaled downwardly from their maximum production proportional to βᵢ. Thus, as a numerical example, consider that:

N_{w}=30,T=100000

Pᵢ=5000,∀i

βᵢ=i/N_{w}∀i

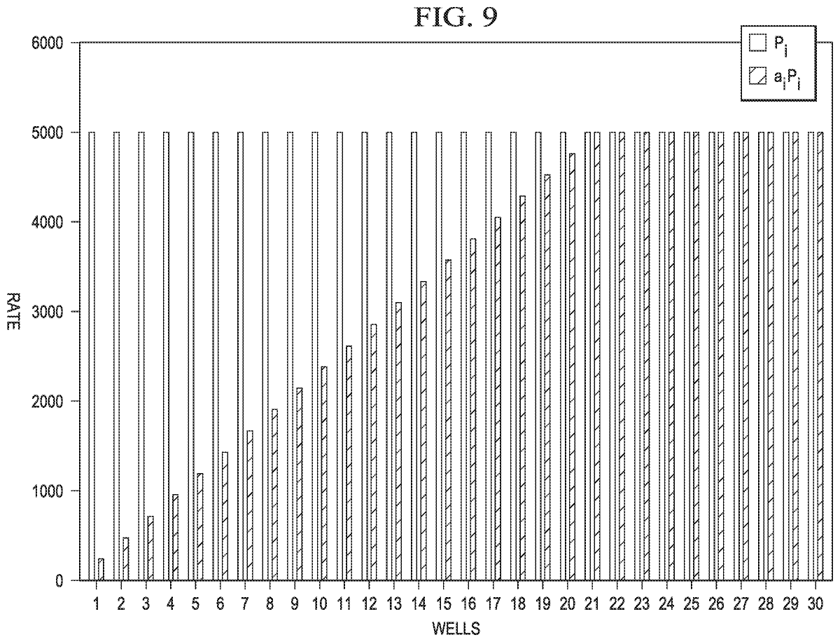

FIG. 9 is an example plot or display of an allocation for the set of wells in the stated numerical example after applying the iterative procedure according to FIG. 8. For the allocation shown in FIG. 9, the set A is i=1, 20, and the proportionality of the well allocation for wells 1 to 20 is clear. Wells 21 through 30 are allocated full production with no proportionality factor applied. If, in situations other the given numerical example, the definition of βᵢ came from a fuzzy scaling where some wells had high water cut, then the resulting allocation would draw more heavily on the wells with the least water.

It can thus be understood that determination of the allocation proportionality βi, is according to the present invention based on analytical principles according to fuzzy logic. By using the linguistic rules in the manner described the intent of a reservoir engineer can be implemented using fuzzy inferences to eventually generate a crisp βᵢ.

The present invention avoids the technological problems caused by previous allocation of production rates among wells according to the complex formula weight rated allocation calculation, or the alternative pro rata allocation with an identical ratio of production for each well of the group. With the present invention it has been found that the fuzzy logic methodology is particularly adapted and particularly suitable by integration into a practical application for production management of wells based on determined allocated well production rates.

### Data Processing System D

As illustrated in FIG. 4, the data processing system D includes a computer 100 having a master node processor 102 and memory 104 coupled to the processor 100 to store operating instructions, control information and database records therein. The data processing system D is preferably a multicore processor with nodes such as those from Intel Corporation or Advanced Micro Devices (AMD), or an HPC Linux cluster computer. The data processing system D may also be a mainframe computer of any conventional type of suitable processing capacity such as those available from International Business Machines (IBM) of Armonk, N.Y. or other source. The data processing system D may in cases also be a computer of any conventional type of suitable processing capacity, such as a personal computer, laptop computer, or any other suitable processing apparatus. It should thus be understood that a number of commercially available data processing systems and types of computers may be used for this purpose.

The computer 100 is accessible to operators or users through user interface 106 and are available for displaying output data or records of processing results obtained according to the present invention with an output graphic user display 108. The output display 108 includes components such as a printer and an output display screen capable of providing printed output information or visible displays in the form of graphs, data sheets, graphical images, data plots and the like as output records or images.

The user interface 106 of computer 100 also includes a suitable user input device or input/output control unit U to provide a user access to control or access information and database records and operate the computer 100. Data processing system D further includes a database of data stored in computer memory, which may be internal memory 104, or an external, networked, or non-networked memory as indicated at 116 in an associated database 118 in a server 120.

The data processing system D includes program code 122 stored in non-transitory memory 104 of the computer 100. The program code 122 according to the present invention is in the form of computer operable instructions causing the data processor 100 to determine allocated production rates among the plurality of production wells W according to the present invention in the manner set forth.

It should be noted that program code 122 may be in the form of microcode, programs, routines, or symbolic computer operable languages capable of providing a specific set of ordered operations controlling the functioning of the data processing system D and direct its operation. The instructions of program code 122 may be stored in memory 104 of the data processing system D, or on computer diskette, magnetic tape, conventional hard disk drive, electronic read-only memory, optical storage device, or other appropriate data storage device having a computer usable non-transitory medium stored thereon. Program code 122 may also be contained on a data storage device such as server 120 as a non-transitory computer readable medium, as shown.

The data processing system D may be comprised of a single CPU, or a computer cluster as shown in FIG. 4, including computer memory and other hardware to make it possible to manipulate data and obtain output data from input data. A cluster is a collection of computers, referred to as nodes, connected via a network. Usually a cluster has one or two head nodes or master nodes 102 used to synchronize the activities of the other nodes, referred to as processing nodes 124. The processing nodes 124 each execute the same computer program and work independently on different segments of the grid which represents the reservoir.

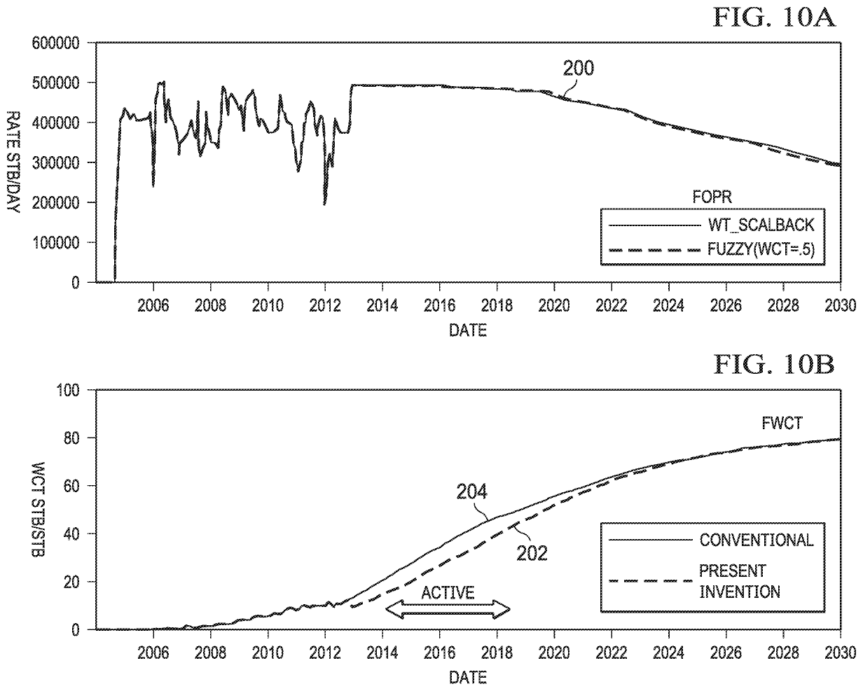

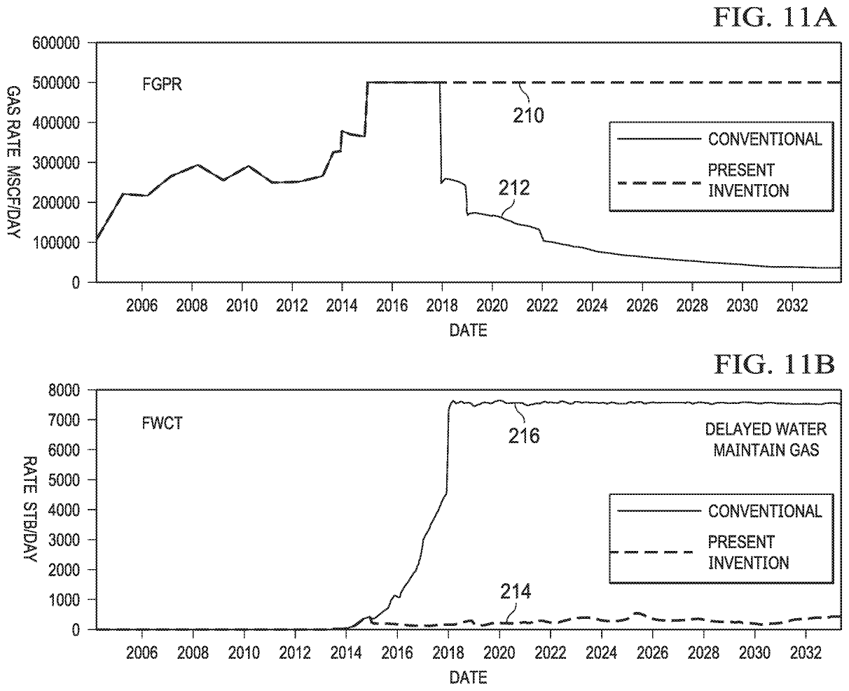

FIGS. 10A and 10B are comparative plots of results as indicated by legends in those figures from reservoir simulation for well production obtained according to the present invention in contrast with conventional methods of production allocation. FIG. 10A is a plot of field oil production rate (FOPR) over past and coming years of projected further production. FIG. 10B is a plot of field water cut (FWCT) over past and coming years of projected further production. As indicated in FIGS. 10A and 10B, respectively, the rate plots for years with dates of 2013 and earlier are results which have been conformed as a result of history match processing, during which allocation method have not been used. Thus, the plots of FOPR and FWCT for those times are identical.

After 2013 the well production allocation according to the present invention was for this example applied where the “VERY-HIGH” water-cut fraction of 0.5 being applied. In this example, a water-cut of 0.5 and above was assigned to the “VERY-HIGH” fuzzy set in the manner described. As indicated at 200 in FIG. 10A, the results show that the target field oil production FOPR is maintained. Further, as shown at 202 in FIG. 10B, production allocation according to the present invention results in lower field water cut FWCT, in comparison to conventional methods of production allocation shown at 204. Thus, unwanted water production from the field is delayed.

FIGS. 11A and 11B are comparative plots of another example of results as indicated by legends in those figures from reservoir simulation for well production obtained according to the present invention in contrast with conventional methods of production allocation. In the example of FIGS. 11A and 11B, the field is one which is producing natural gas. FIG. 11A is a plot of field gas production rate (FGPR) over past and coming years of projected further production. FIG. 11B is a plot of field water cut (FWCT) over past and coming years of projected further production.

As indicated at 210 in FIG. 11A, the results show that the gas target or plateau production is significantly extended over time in comparison with conventionally determined production allocation shown at 212. Further, as shown at 214 in FIG. 11B, production allocation according to the present invention results in continuing lower field water cut FWCT and a limit or constraint on field water production has not been violated. This is in comparison to high water cut indicated at 216 from conventional methods of production allocation.

It can thus be appreciated that the present invention provides a methodology for production management of wells based on determined allocated well production rates where Fuzzy logic technology is used to define a fuzzy-potential for each well. The present invention receives production related inputs such as water-cut, gas-oil-ratio, and maximum flow rate of the well. These inputs are split into fuzzy sets and then linguistic rules are applied, these rules are straightforward and understandable by both the reservoir engineer and the simulator developer. The Fuzzy sets are de-fuzzified and the resulting crisp value is provided to the well-management system of the simulator, so that each well is allocated a rate proportional to the accordingly allocated potential of the well.

The invention has been sufficiently described so that a person with average knowledge in the field of reservoir modeling and simulation may reproduce and obtain the results mentioned herein described for the invention. Nonetheless, any skilled person in the field of technique, subject of the invention herein, may carry out modifications not described in the request herein, to apply these modifications to a determined structure and methodology, or in the use and practice thereof, requires the claimed matter in the following claims; such structures and processes shall be covered within the scope of the invention.

It should be noted and understood that there can be improvements and modifications made of the present invention described in detail above without departing from the spirit or scope of the invention as set forth in the accompanying claims.

What is claimed is:

1. A method of controlling production of a hydrocarbon fluid at an assigned production target rate from a plurality of production wells of a subsurface hydrocarbon reservoir with a well production and control system, based on allocated production rates among the plurality of production wells determined by a data processing system, the data processing system having a processor, a memory and a reservoir simulator, the method comprising the processing steps of:
(a) receiving in the data processing system memory real time production pressure and flow rates during production of fluids from the production wells,
(b) receiving in the data processing system memory real time downhole pressure measures during the production of fluids in the production wells,
(c) receiving in the data processing system memory a target production rate for hydrocarbons from the group of wells;
(d) determining in the data processing system processor production allocations for individual wells of the group of wells;
(e) performing in the reservoir simulator a simulation of production of fluids from the individual wells of the reservoir to determine whether the allocated production from the wells matches the well group reduction target rate; and
(f) adjusting production rates of the production wells with the well production and control system based on the determined production allocation rates among the wells of the reservoir.

2. The method of claim 1, wherein the well production and control system includes permanent downhole pressure measurement sensors installed in less than all of the production wells to measure downhole pressure for such production wells to serve as observation wells.

3. The method of claim 2, wherein the step of receiving in the data processing system memory real time downhole pressure measures comprises receiving from the downhole sensors in the observation wells based on measurements from the permanent downhole pressure measurement sensors during the production of fluids in the observation wells.

4. The method of claim 3, wherein the step of determining in the data processing system processor production allocations comprises determining in the data processing system processor production allocations for individual wells of the group of wells based on measurements from the permanent downhole pressure measurement sensors during the production of fluids in the observation wells.

5. The method of claim 1, wherein the reservoir further comprises a plurality of injection wells for injection of fluids into the reservoir to stimulate production from the reservoir.

6. The method of claim 5, wherein the well production and control system includes permanent downhole pressure measurement sensors installed in less than all of the injection wells to measure downhole pressure for such injection wells to serve as observation wells.

7. The method of claim 6, wherein the step of receiving in the data processing system memory real time downhole pressure measures comprises receiving pressure measures from the downhole sensors in the observation wells based on measurements from the permanent downhole pressure measurement sensors during the production of fluids in the observation wells.

8. The method of claim 7, wherein the step of determining in the data processing system processor production allocations comprises determining in the data processing system processor production allocations for individual wells of the group of wells based on measurements from the permanent downhole pressure measurement sensors during the production of fluids in the observation wells.

9. The method of claim 1, wherein the step of determining in the data processing system processor production allocations comprises the steps of:
(a) receiving defined input production and parameter quantities for individual wells in the group;
(b) generating values for production rules for the individual wells in the group based on the defined input production and parameter quantities; and
(c) storing the generated values for the production rules for the individual wells in the group.

10. The method of claim 9, further including the step of forming an output display of the generated values for the production rules for the individual wells in the group.

11. The method of claim 9, further including the step of generating normalized parameter quantities for the individual wells in the group based on the received defined input production and parameter quantities for the individual wells.

12. The method of claim 11, further including the step of applying rules for production rates for individual wells in the group based on the generated normalized parameter quantities for the individual wells.

13. The method of claim 1, wherein the hydrocarbon fluid comprises oil.

14. The method of claim 1, wherein the hydrocarbon fluid comprises gas.

15. A system for controlling production of a hydrocarbon fluid at an assigned production target rate from a plurality of production wells of a subsurface hydrocarbon reservoir with a well production and control system, based on allocated production rates among the plurality of production wells, the system comprising:
(a) a well production and control system to control production of fluids from individual production wells of the plurality of production wells;
(b) a plurality of permanent downhole pressure measurement sensors in less than all of the production wells to measure downhole pressure for such production wells to serve as observation wells;
(c) a data processing system determining allocated production rates among the plurality of wells, the data processing system comprising:
(1) a memory receiving real time production pressure and flow rates during production of fluids from the production wells,
(2) the memory further real time downhole pressure measures during the production of fluids in the production wells;
(3) the memory further receiving a target production rate for hydrocarbons from the group of wells;
(4) a processor determining production allocations for individual wells of the group of wells;
(5) a reservoir simulator performing a simulation of production of fluids from the individual wells of the reservoir to determine whether the allocated production from the wells matches the well group reduction target rate; and
(d) the well production and control system adjusting production rates of the production wells based on the determined production allocation rates among the wells of the reservoir.

16. The system of claim 15, wherein the well production and control system includes permanent downhole pressure measurement sensors installed in less than all of the production wells to measure downhole pressure for such production wells to serve as observation wells.

17. The system of claim 16, wherein the memory receives pressure measures from the downhole sensors in the observation wells based on measurements from the permanent downhole pressure measurement sensors during the production of fluids in the observation wells.

18. The system of claim 17, wherein the processor determines production allocations for individual wells of the group of wells based on measurements from the permanent downhole pressure measurement sensors during the production of fluids in the observation wells.

19. The system of claim 15, wherein the reservoir further comprises a plurality of injection wells for injection of fluids into the reservoir to stimulate production from the reservoir.

20. The system of claim 19, wherein the well production and control system includes permanent downhole pressure measurement sensors installed in less than all of the injection wells to measure downhole pressure for such injection wells to serve as observation wells.

21. The system of claim 20, wherein memory receive pressure measures from the downhole sensors in the observation wells based on measurements from the permanent downhole pressure measurement sensors during the injection of fluids in the observation wells.

22. The system of claim 21, wherein the processor determines production allocations for individual wells of the group of wells based on measurements from the permanent downhole pressure measurement sensors during the injection of fluids in the observation wells.

23. The system of claim 15, wherein the processor in determining production allocations performs the steps of:
(a) receiving defined input production and parameter quantities for individual wells in the group;
(b) generating values for production rules for the individual wells in the group based on the defined input production and parameter quantities; and
(c) storing the generated values for the production rules for the individual wells in the group.

24. The system of claim 23, wherein the data processing system further includes an output display forming images of the generated values for the production rules for the individual wells in the group.

25. The system of claim 23, further including the processor performing the step of generating normalized parameter quantities for the individual wells in the group based on the received defined input production and parameter quantities for the individual wells.

26. The method of claim 25, further including the processor performing the step of applying rules for production rates for individual wells in the group based on the generated normalized parameter quantities for the individual wells.

27. The system of claim 15, wherein the hydrocarbon fluid comprises oil.

28. The system of claim 15, wherein the hydrocarbon fluid comprises gas.

29. A data storage device having stored in a non-transitory computer readable medium computer operable instructions for causing a data processing system to control production of a hydrocarbon fluid at an assigned production target rate from a plurality of production wells of a subsurface hydrocarbon reservoir with a well production and control system, based on allocated production rates among the plurality of production wells determined by a data processing system, the data processing system having a processor, a memory and a reservoir simulator, the instructions stored in the data storage device causing the data processing system to perform the following steps:
(a) receiving in the data processing system memory real time production pressure and flow rates during production of fluids from the production wells,
(b) receiving in the data processing system memory real time downhole pressure measures during the production of fluids in the production wells;
(c) receiving in the data processing system memory a target production rate for hydrocarbons from the group of wells;
(d) determining in the data processing system processor production allocations for individual wells of the group of wells; and
(e) performing in the reservoir simulator a simulation of production of fluids from the individual wells of the reservoir to determine whether the allocated production from the wells matches the well group reduction target rate for adjusting production rates of the production wells with the well production and control system based on the determined production allocation rates among the wells of the reservoir.

30. The data storage device of claim 29, wherein the stored instructions further comprise instructions causing the data processing system to perform the steps of:
(a) receiving defined input production and parameter quantities for individual wells in the group;
(b) generating values for production rules for the individual wells in the group based on the defined input production and parameter quantities; and
(c) storing the generated values for the production rules for the individual wells in the group.

31. The data storage device of claim 30, wherein the stored instructions further comprise instructions causing the data processing system to perform the step of forming an output display of the generated values for the production rules for the individual wells in the group.

32. The data storage device of claim 30, wherein the stored instructions further comprise instructions causing the data processing system to perform the step of generating normalized parameter quantities for the individual wells in the group based on the received defined input production and parameter quantities for the individual wells.

33. The data storage device of claim 32, wherein the stored instructions further comprise instructions causing the data processing system to perform the step of applying rules for production rates for individual wells in the group based on the generated normalized parameter quantities for the individual wells.
